(19) United States
(12) Patent Application Publication
(10) Pub. No.: US 2013/0069223 A1
(43) Pub. Date: Mar. 21, 2013

(54) FLASH MEMORY CARD WITHOUT A SUBSTRATE AND ITS FABRICATION METHOD

(71) Applicant: Hui-Chang CHEN, Hukou Shiang (TW)

(72) Inventor: Hui-Chang CHEN, Hukou Shiang (TW)

(21) Appl. No.: 13/234,691

(22) Filed: Sep. 16, 2011

(51) Int. Cl. H01L 23/48; H01L 21/56

(52) U.S. Cl. 257/737; 438/124; 257/E23.021; 257/E23.011; 257/E21.059

(57) ABSTRACT

Disclosed is a flash memory card without a substrate, primarily comprising a memory chip component, a controller chip disposed on the memory chip, and an encapsulant encapsulating both chips. Formed on an active surface and a back surface of the memory chip component are a first RDL (redistribution layer) and a second RDL respectively. A plurality of TSVs (through silicon vias) penetrate from the active surface to the back surface to electrically connect both RDLs. A plurality of contacting fingers are disposed on the back surface of the memory chip component and electrically connected with the second RDL. Additionally, the encapsulant has a card appearance with one surface of each contacting finger to be exposed. Accordingly, the flash memory card can save conventional substrate structure with better reliability and efficiency for packaging processes.

### FIELD OF THE INVENTION

The present invention relates to a packaging technology of semiconductor devices, and more specifically to a flash memory card without a substrate and its fabrication method.

### BACKGROUND OF THE INVENTION

A conventional flash memory card has a substrate with circuitry on a core made of glass fiber mixed with resin as a chip carrier to carry a memory chip and a controller chip which are encapsulated inside the flash memory card. However, the bottom surface of the substrate is exposed to dispose contacting fingers as the external electrical terminals for a flash memory card. Besides the issue of higher packaging cost, the flash memory card is vulnerable for substrate peeling or worn out under long-term usage.

In order to reduce the packaging cost, Takiar et al. disclosed a flash memory card using a leadframe as a chip carrier to replace a substrate as revealed in U.S. Pat. No. 7,795,715 B2 where the leadframe has a die pad to carry the chip, contacting pads, and leads to connect to the contacting pads in each unit area. However, the contacting pads are directly connected to the metal frame outside the molding area or connected through the individual tie bars. After the flash memory card is singulated, there are a plurality of cut sides of the contact pads or tie bars exposed from the sidewalls of the encapsulant which is not suitable for the protection of flash memory cards in usage and from moisture. Furthermore, the thickness of flash memory cards increases if substrates or leadframes are implemented as chip carriers where available space for disposing dice is reduced.

### SUMMARY OF THE INVENTION

The main purpose of the present invention is to provide a flash memory card without a substrate and its fabrication method for packaging memory chip components with larger dimensions in a flash memory card and to resolve the packaging issues of conventional flash memory card using substrates as chip carriers and to further simplify or eliminate wire-bonding processes.

The second purpose of the present invention is to provide a flash memory card without a substrate and its fabrication method where a memory chip component having a plurality of through silicon vias (TSVs) and double-sided RDL circuitry to carry a controller chip with contacting fingers directly disposed on it to eliminate substrates in a conventional flash memory card to increase the packaging efficiency to achieve lower packaging cost.

According to the present invention, a flash memory card without a substrate is revealed, primarily comprising a memory chip component, a first RDL (redistribution layer), a second RDL, a plurality of contacting fingers, a controller chip, and an encapsulant. The memory chip component has an active surface and a back surface where a plurality of bonding pads are disposed on the active surface. The memory chip component further has a plurality of TSVs penetrating from the active surface to the back surface. The first RDL is disposed on the active surface of the memory chip component and electrically connects a plurality of redistributed pads to TSVs and to the bonding pads. The contacting fingers are disposed on the back surface of the memory chip component. The second RDL is disposed on the back surface of the memory chip component to electrically connect the contacting fingers to TSVs. The controller chip is disposed on the active surface of the chip to electrically connect to the redistributed pads. The encapsulant has a card appearance and encapsulates the memory chip component and the controller chip with one surface of each contacting finger exposed. Furthermore, a manufacture method of the flash memory card is also revealed in the present invention with the most special characteristic of wafer-level manufacture processes of providing the memory chip component, disposing the first RDL, disposing the second RDL, and disposing the contacting fingers. Moreover, processes of controller chip disposition, processes of electrical connection, and processes of encapsulant formation are all completed by using a bottom mold of a molding carrier as chip carriers to increase overall packaging processes to achieve cost reduction.

The flash memory card without a substrate according to the present invention has the following advantages and effects:
1. Through a flash memory card without a substrate as a technical mean, the packaging issues of a conventional flash memory card using substrates as chip carriers can be resolved to further simplify or eliminate wire-bonding processes.
2. Through a memory chip component having TSVs and double-sided RDLs circuitry to carry a controller chip with contacting fingers directly disposed on it as a technical mean, substrates in a conventional flash memory card can be eliminated to increase the packaging efficiency to achieve lower packaging cost.

### DESCRIPTION OF THE DRAWINGS

FIG. 1 is a cross-sectional component view of a flash memory card without a substrate according to the first embodiment of the present invention.

FIG. 2 is a perspective top view seeing through the encapsulant of a flash memory card as shown in FIG. 1 according to the first embodiment of the present invention.

FIG. 3 is a top view of the active surface of a memory chip component to illustrate a first RDL of a flash memory card according to the first embodiment of the present invention.

FIGS. 4A to 4F are cross-sectional component views illustrating the wafer-level processing steps during the manufacture method of the flash memory card according to the first embodiment of the present invention.

FIG. 5 is a three-dimensional view of a molding carrier for forming an encapsulant of a flash memory card according to the first embodiment of the present invention.

FIGS. 6A to 6E are top component views illustrating the processing steps using a bottom mold of a molding carrier as a chip carrier during the manufacture method of the flash memory card according to the first embodiment of the present invention.

FIG. 7 is a three-dimensional view illustrating the top mold clamping to the bottom mold of the molding carrier according to the first embodiment of the present invention.

FIG. 8 is a cross-sectional view illustrating the formation of the encapsulant after the top mold clamping to the bottom mold of the molding carrier according to the first embodiment of the present invention.

FIG. 9 is a cross-sectional component view of a flash memory card without a substrate according to the second embodiment of the present invention.

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

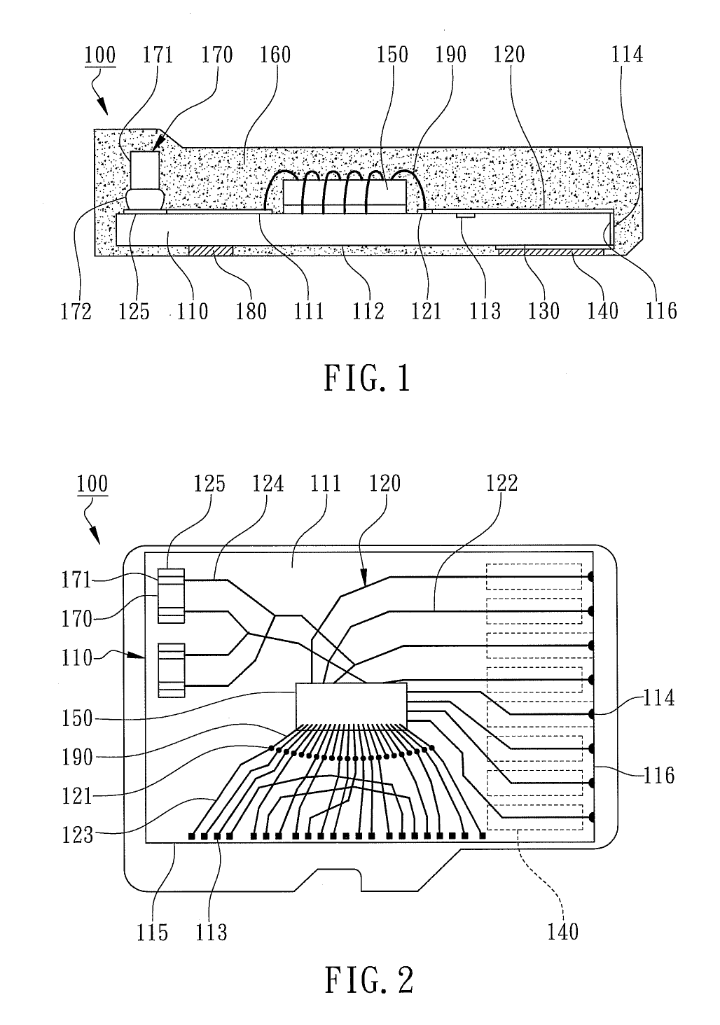

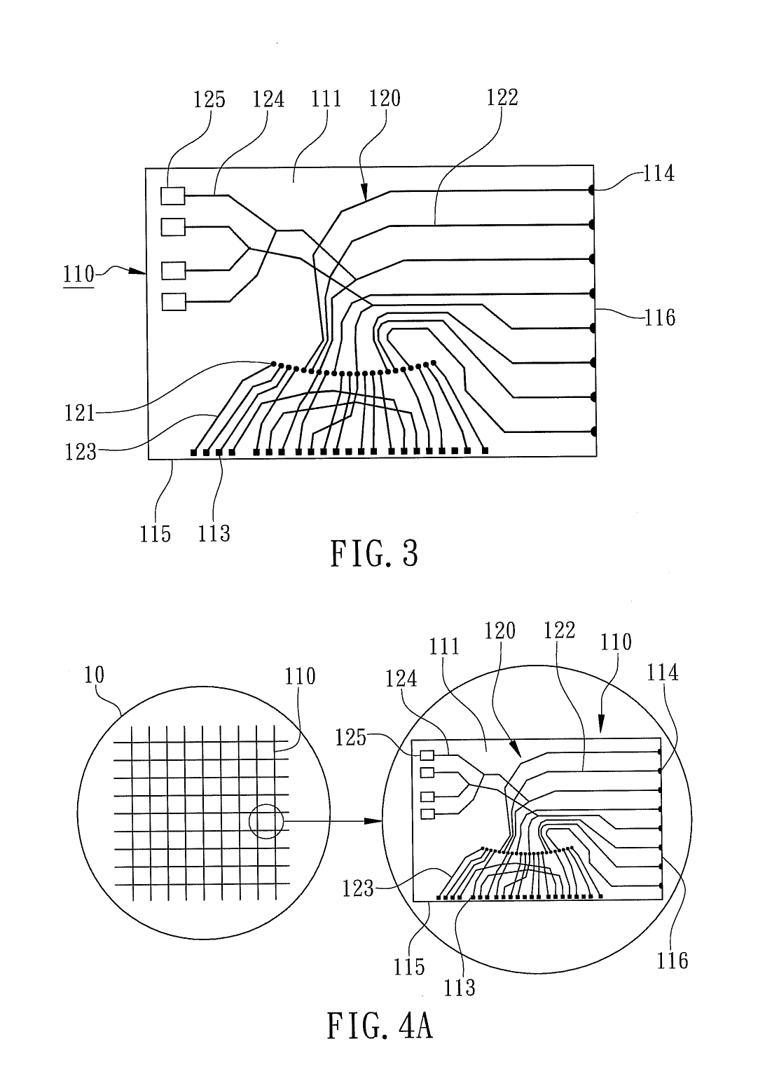

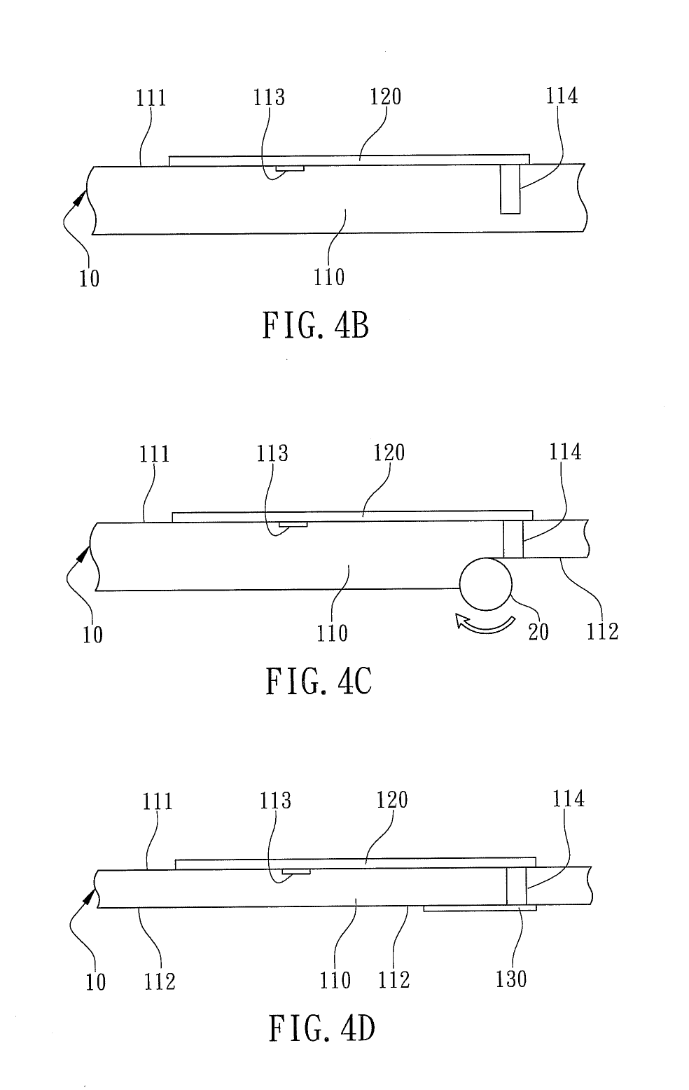

According to the first embodiment of the present invention, a flash memory card without a substrate is revealed where a cross-sectional view is illustrated in FIG. 1 and a perspective top view is illustrated in FIG. 2. The flash memory card 100 without a substrate primarily comprises a memory chip component 110, a first RDL 120, a second RDL 130, a plurality of contacting fingers 140, a controller chip 150, and an encapsulant 160 where the memory chip component 100 has an active surface 111 and a back surface 112 with the first RDL 120 disposed on the active surface 111 of the memory chip component 110 as shown in FIG. 3.

The memory chip component 110 has a plurality of bonding pads 113 disposed on the active surface 111 where the active surface 111 includes memory IC circuitry and the bonding pads 113 are external electrical terminals of memory IC circuitry. The back surface 112 is another surface opposing to the active surface 111 of the memory chip component 110. The memory chip component 110 further has a plurality of TSVs 114 (Through Silicon Vias) penetrating from the active surface 111 to the back surface 112 where TSVs 114 serve as electrical interconnection with plated conductive layers or filled conductive materials. In the present embodiment, the memory chip component 110 is a memory chip with a larger dimension with the active surface 111 occupied more than 70% area of the flash memory card 100.

The first RDL 120 includes a plurality of redistributed pads 121. The disposition of the first RDL 120 is to electrically connect the redistributed pads 121 to TSVs 114 and to the bonding pads 113. In the present embodiment, as shown in FIG. 3, besides the redistributed pads 121, the first RDL 120 further includes at least a first circuitry 122 and at least a second circuitry 123 where the first circuitry 122 electrically connects the redistributed pads 121 to TSVs 114 and the second circuitry 123 electrically connects the redistributed pads 121 to the bonding pads 113.

Moreover, the second RDL 130 is disposed on the back surface 112 of the memory chip component 110 to electrically connect to TSVs 114. The contacting fingers 140 are disposed on the back surface 112 of the memory chip component 110. The second RDL 130 electrically connects the contacting fingers 140 to TSVs 114. The thickness of the contacting fingers 140 should be several times or more than ten times the thickness of the second RDL 130 to serve as the external contacting terminals of the flash memory card 100. To be more specific, the contacting fingers 140 are made of Cu/Ni/Au layers which can be formed by plating during wafer-level processes when the contacting fingers 140 are stacked on the second RDL 130. In a various embodiment, the contacting fingers 140 can be formed by soldering leads of a leadframe to the second RDL 130 on the back surface 112 of the memory chip component 110.

In the present embodiment, the memory chip component 110 further has a first sidewall 115 adjacent to the bonding pads 113 and a second sidewall 116 adjacent to the contacting fingers 140 where TSVs 114 are located at the second sidewall 116. Therefore, the disposition of TSVs 114 will not impact IC layout and circuitry nor weaken the structure and die strength of the memory chip component 110. Furthermore, the trace length of the second RDL 130 between the contacting fingers 140 and TSVs 114 can be shortened.

Normally, the dimension of the controller chip 150 is smaller than the dimension of the memory chip component 110 so that the controller chip 150 can be disposed on top of the memory chip component 110. The controller chip 150 is disposed on the active surface 111 of the memory chip component 110 and is electrically connected to the redistributed pads 121. In the present embodiment, the bonding pads of the controller chip 150 can electrically connect to the redistributed pads 121 by a plurality of bonding wires 190 formed by wire-bonding processes. In the afore described flash memory card 100, the first RDL 120 further includes a plurality of soldering pads 125 disposed on the active surface 111 where at least a third circuitry 124 electrically connects the soldering pads 125 to the corresponding first circuitry 122. The flash memory card 100 further comprises at least a passive component 170 disposed on the active surface 111 of the memory chip component 110 where the passive component 170 has a plurality of electrodes 171 which is soldered to the soldering pads 125 by solder paste 172 so that various electronic components can be integrated on the active surface 111 of the memory chip component 110.

The encapsulant 160 has a card appearance to encapsulate the memory chip component 110 and the controller chip 150 to expose one surface 141 of each contacting finger 140. In the present embodiment, the card appearance and format is a micro SD card, however, without any limitation, the card can be an eMMC. Moreover, the encapsulant 160 further encapsulates the passive component 170. In a more specific structure, the encapsulant 160 can further encapsulate the back surface 112 of the memory chip component 110 to effectively and completely seal and protect the memory chip component 110. Preferably, the flash memory card 100 further has a spacing bump 180 disposed on the back surface 112 of the memory chip component 110 to match the disposition of the contacting fingers 140 to avoid tilting of the memory chip component 110 during die attaching, wire bonding, and encapsulating processes to keep a constant encapsulating thickness on the back surface 112. The material of the spacing bump 180 can be insulated material such as polyimide (PI). In the present embodiment, the encapsulant 160 is directly encapsulated the first RDL 120 and the second RDL 130 to save the covering materials on the wafer surface.

Therefore, the flash memory card according to the present invention can be implemented to package a memory chip with a larger dimension to resolve the packaging issues of a conventional flash memory card using substrates as chip carriers and to further simplify or eliminate wire-bonding processes. Furthermore, a memory chip component having TSVs and double-sided RDL circuitry to carry a controller chip with contacting fingers directly disposed on it to eliminate substrates in a conventional flash memory card to increase the packaging efficiency to achieve lower packaging cost.

The manufacture processes of the afore flash memory card 100 is described in detail as follows:

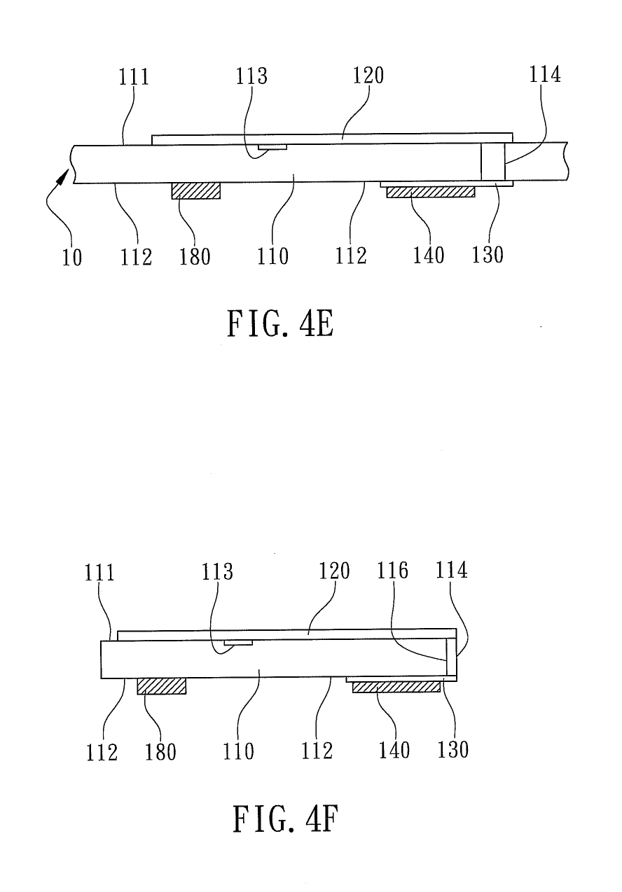

Firstly, as shown in FIG. 4A and FIG. 4B, a memory chip component 110 is provided having an active surface 111 and a back surface without backside grinding where a plurality of bonding pads 113 are disposed on the active surface 111 and a plurality of TSVs 114 are formed on the active surface 111 of the memory chip component 110. In this step, the memory chip component 110 is fabricated on a wafer 10 where the thickness of the wafer 10 before backside grinding processes is larger than the depth of TSVs 114. Moreover, the first RDL 120 is fabricated on the active surface 111 of the memory chip component 110 by wafer-level IC fabrication technology to electrically connect the redistributed pads 121 to TSVs 114 and to the bonding pads 113.

Then, the manufacture method of the present invention further comprises a backside grinding process on the back surface of the wafer. As shown in FIG. 4C, a backside grinding device 20 such as a grinding wheel is implemented to backside grind the non-active surface of the wafer 10 to reduce the thickness of the wafer 10 to form the back surface 112 of the memory chip component 110 to expose one end of TSVs 114 from the back surface 112 of the memory chip component 110. Therefore, before backside grinding processes, TSVs 114 do not need to penetrate through the memory chip component 110 during wafer-level processes. After backside grinding processes, TSVs 114 of the memory chip component 110 become penetrating from the active surface 111 to the back surface 112.

Then, as shown in FIG. 4D, the second RDL 130 is fabricated on the back surface 112 of the memory chip component 110 by wafer-level IC fabrication technology to electrically connect to TSVs 114.

Then, as shown in FIG. 4E, a plurality of contacting fingers 140 are fabricated on the back surface 112 of the memory chip component 110 by wafer-level IC fabrication technology to electrically connect to the second RDL 130. The spacing bump 180 is disposed on the back surface 112 of the memory chip component 110 without electrical connecting to TSVs 114. After wafer singulation processes, the memory chip components 110 fabricated on the wafer 10 become a plurality of individual memory chip components 110 as shown in FIG. 4F. Furthermore, the first sidewall 115 and the second sidewall 116 of the memory chip component 110 are formed after wafer singulation processes where TSVs 114 is located at the second sidewall 116 as shown in FIG. 3. The afore described processing steps of the memory chip component 110 are wafer-level front-end packaging processes.

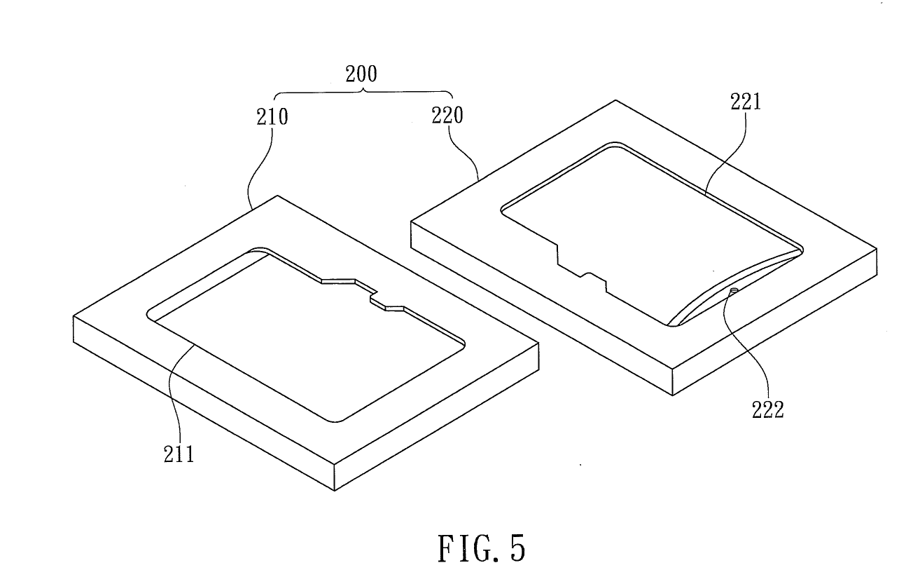

As shown in FIG. 5, a molding carrier 200 is provided having a bottom mold 210 and a top mold 220 to form the encapsulant 160 where the bottom mold 210 is used as a chip carrier for back-end packaging processes. The bottom mold 210 of the molding carrier 200 has a bottom mold cavity 211 having a shape of a memory card with a dimension slightly larger than the dimension of the memory chip component 110 to define the card appearance so that there is no need for the memory card singulation processes nor grinding processes after the formation of the encapsulant 160 by molding processes. In the present embodiment, the top mold 220 also has a top mold cavity 221 corresponding to the shape of the bottom mold cavity 211. In a various embodiment, the top mold can be a flat mold if the depth of the bottom mold cavity 211 is enough.

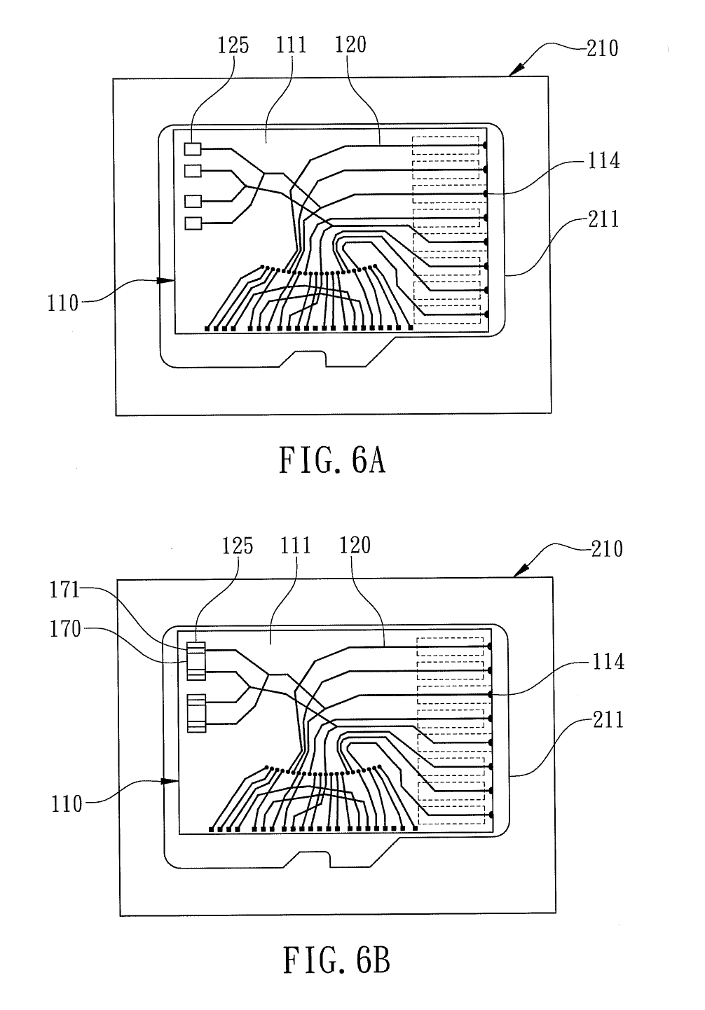

As shown in FIG. 6A, the memory chip component 110 is placed inside the bottom mold 210 of the molding carrier 200 with the active surface 111 of the memory chip component 110 faced downward to the opening of the bottom mold cavity 211 of the bottom mold 210. In a preferred embodiment, since the first RDL 120 includes a plurality of soldering pads 125 on the active surface 111, the fabrication processes further comprise the following steps as shown in FIG. 6B. When the bottom mold 210 of the molding carrier 200 serves as a chip carrier, at least a passive component 170 is disposed on the active surface 111 of the memory chip component 110 where the passive component 170 has a plurality of electrodes 171 bonded to the soldering pads 125. Therefore, the disposition process of the passive component 170 can perfectly meet the requirements and fit into the back-end packaging processes using the bottom mold 210 of the molding carrier 200 as a chip carrier.

Moreover, as shown in FIG. 6C, when the bottom mold 210 of the molding carrier 200 serves as a chip carrier, the controller chip 150 is disposed on top of the active surface 111 of the memory chip component 110. The afore described disposition step of the controller chip 150 further comprises the following step as shown in FIG. 6D. When the bottom mold 210 of the molding carrier 200 serves as a chip carrier, the controller chip 150 is electrically connected to the redistributed pads 121 by a plurality of bonding wires 190 formed by wire-bonding processes. Therefore, this wire-bonding process can perfectly meet the requirements and fit into the back-end packaging processes using the bottom mold 210 of the molding carrier 200 as a chip carrier.

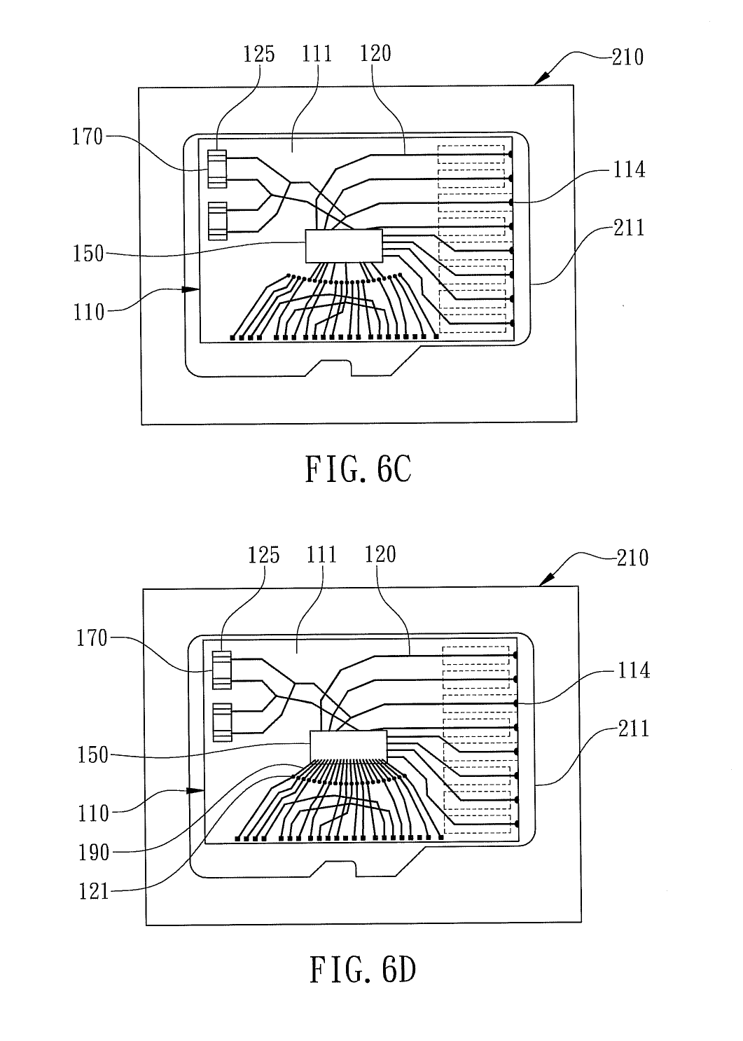

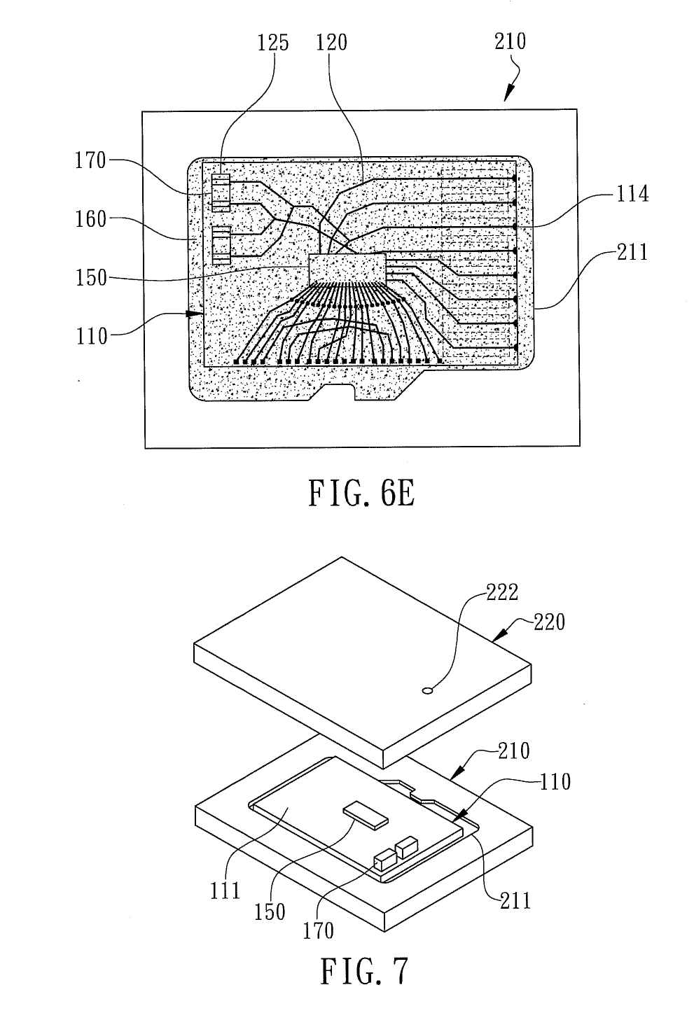

As shown in FIG. 7 and FIG. 8, the top mold 220 of the molding carrier 200 is clamped to the bottom mold 210 where the memory chip component 110, the controller chip 150, and the passive component 170 are all accommodated inside the mold cavity between the bottom mold cavity 211 of the bottom mold 210 and the top mold cavity 221 of the top mold 220. As shown in FIG. 6E, the encapsulant 160 is formed inside the molding carrier 200 where the uncured encapsulant 160 completely fills the bottom mold cavity 211 of the bottom mold 210 as well as the top mold cavity 221 of the top mold 220. The uncured encapsulant 160 can be thermosetting and non-conductive epoxy. After curing processes, the encapsulant 160 has a card appearance to encapsulate the memory chip component 110 and the controller chip 150 with one surface 141 of the contacting finger 150 exposed from the encapsulant 160. Furthermore, there are different molding configuration and set-up according to different molding methods. When the encapsulant 160 is formed by transfer mold, the top mold 220 has a gate 222 connected to the top mold 221 or to the bottom mold 211. When the encapsulant 160 is formed by compression mold, the top mold has no gate. After encapsulation, the flash memory card 100 can be ejected from the bottom cavity 211 by a plurality of ejecting pins stick out from the bottom cavity 211 of the bottom mold 210.

Therefore, the manufacture method of the flash memory card 100 without a substrate as revealed in the present invention with the most special characteristic of wafer-level manufacture processes of providing the memory chip component 110, disposing the first RDL 120, disposing the second RDL 130, and disposing the contacting fingers 140. Moreover, disposition processes of the controller chip 150, processes of electrical connection, and formation processes of the encapsulant 160 are all completed when using the bottom mold 210 of the molding carrier 200 to be a chip carrier to accelerate overall packaging processes to achieve cost reduction.

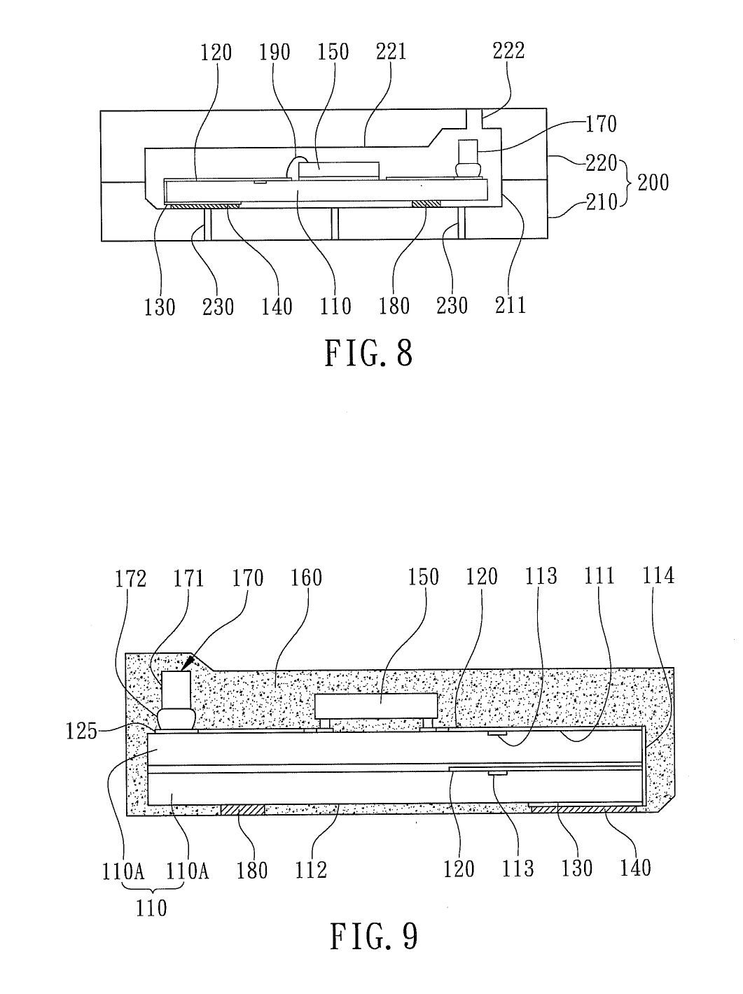

Moreover, the memory chip component 100 can be a single memory die, a stack of memory dices or a wafer level chip scale package. In the afore described embodiment, the memory chip component 110 is a single memory die. As shown in FIG. 9, in a various embodiment, the memory chip component 110 is a stack of memory dices by stacking a plurality of memory dices 110A. A first RDL 120 is disposed on the active surface 111 of each memory die 110A where the second RDL is only disposed on the external exposed surface 112 of a bottom memory die 110A. The first RDLs 120 of the memory dies 110A and the second RDL 130 are electrically connected to each other by TSVs 114. Furthermore, the controller chip 150 is flip-chip bonded on the external exposed active surface 111 of an upper memory die 110A.

The above description of embodiments of this invention is intended to be illustrative but not limited. Other embodiments of this invention will be obvious to those skilled in the art in view of the above disclosure which still will be covered by and within the scope of the present invention even with any modifications, equivalent variations, and adaptations.

What is claimed is:

1. A flash memory card comprising:
a memory chip component having an active surface and a back surface, wherein a plurality of bonding pads are disposed on the active surface, and the memory chip component further has a plurality of through silicon vias penetrating from the active surface to the back surface;
a first redistribution layer disposed on the active surface of the memory chip component and including a plurality of redistributed pads electrically connected to the through silicon vias and to the bonding pads;
a plurality of contacting fingers disposed on the back surface of the memory chip component;
a second redistribution layer disposed on the back surface of the memory chip component to electrically connect the contacting fingers to the through silicon vias;
a controller chip disposed on the active surface of the memory chip component and electrically connected to the redistributed pads; and
an encapsulant having a card appearance and encapsulating the memory chip component and the controller chip with one surface of each contacting finger exposed.

2. The flash memory card as claimed in claim 1, wherein the first redistribution layer further includes a plurality of soldering pads disposed on the active surface and the flash memory card further comprises at least a passive component disposed on the active surface of the memory chip component, wherein the passive component has a plurality of electrodes physically and electrically connected to the soldering pads.

3. The flash memory card as claimed in claim 2, wherein the first redistribution layer further includes a first circuitry, a second circuitry and a third circuitry, wherein the first circuitry electrically connects the redistributed pads to the through silicon vias, wherein the second circuitry electrically connects the redistributed pads to the bonding pads, wherein the third circuitry electrically connects the soldering pads to the first circuitry.

4. The flash memory card as claimed in claim 1, wherein the encapsulant further encapsulates the back surface of the memory chip component.

5. The flash memory card as claimed in claim 4, further comprising at least a spacing bump disposed on the back surface of the memory chip component.

6. The flash memory card as claimed in claim 1, wherein the encapsulant directly encapsulates the first redistribution layer and the second redistribution layer.

7. The flash memory card as claimed in claim 1, wherein the contacting fingers are made of plated Cu/Ni/Au.

8. The flash memory card as claimed in claim 1, wherein the memory chip component further has a first sidewall adjacent to the bonding pads and a second sidewall adjacent to the contacting fingers, wherein the through silicon vias are located at the second sidewall.

9. The flash memory card as claimed in claim 1, wherein the contacting fingers are stacked on the second redistribution layer.

10. A manufacture method of a flash memory card, comprising:
providing a memory chip component having an active surface and a back surface, wherein a plurality of bonding pads are disposed on the active surface and the memory chip component further has a plurality of through silicon vias penetrating from the active surface to the back surface;
disposing a first redistribution layer with wafer-level processes on the active surface of the memory chip component, wherein the first redistribution layer includes a plurality of redistributed pads electrically connected to the through silicon vias and the bonding pads;
disposing a second redistribution layer with wafer-level processes on the back surface of the memory chip component to electrically connect to the through silicon vias;
disposing a plurality of contacting fingers with wafer-level processes on the back surface of the memory chip component, wherein the contacting fingers are electrically connected with the second redistribution layer;
disposing the memory chip component inside a bottom mold of a molding carrier;
disposing a controller chip on the active surface of the memory chip component by using the bottom mold of the molding carrier as a chip carrier, wherein the controller chip is electrically connected to the redistributed pads; and
forming an encapsulant inside the molding carrier when a top mold of the molding carrier is clamped to the bottom mold, wherein the encapsulant has a card appearance and encapsulates the memory chip component and the controller chip with one surface of each contacting finger exposed.

11. The method as claimed in claim 10, wherein the first redistribution layer further includes a plurality of soldering pads disposed on the active surface of the memory chip component, the manufacture method further comprising the step of: disposing a passive component on the active surface of the memory chip component, wherein the passive component has a plurality of electrodes physically and electrically connected to the soldering pads.

12. The method as claimed in claim 10, wherein the memory chip component is fabricated on a wafer and after the disposition of the first redistribution layer and before the disposition of the second redistribution layer, the manufacture method further comprising the step of wafer backside grinding to make one ends of the through silicon vias exposed from the back surface of the memory chip component.

13. The method as claimed in claim 10, wherein the step of disposing the controller chip includes forming a plurality of bonding wires by wire-bonding to electrically connect the controller chip to the redistributed pads.

14. The method as claimed in claim 10, wherein the bottom mold of the molding carrier has a bottom mold cavity with a dimension slightly larger than the dimension of the memory chip component to define the card appearance.
